(19) United States
(12) Patent Application Publication
(10) Pub. No.: US 2026/0206595 A1
(43) Pub. Date: Jul. 16, 2026

(54) Process and Structure to Enable the Integration of 3rd Party Die Among Hybrid Bond Technologies

(71) Applicant: Apple Inc., Cupertino, CA (US)

(72) Inventors: Weiming Chris Chen, Baoshan Township (TW); Vidhya Ramachandran, Cupertino, CA (US); Young Doo Jeon, San Jose, CA (US); Ying-Chieh Ke, Taoyuan (TW); Jun Zhai, Cupertino, CA (US)

(21) Appl. No.: 19/023,005

(22) Filed: Jan. 15, 2025

(51) Int. Cl. H01L 23/58; H01L 21/48; H01L 23/00; H01L 23/498; H01L 25/16; H10B 80/00

(52) U.S. Cl. CPC H10W 42/00; H10W 70/093; H10W 90/00; H10W 90/701; H10B 80/00; H10W 80/312; H10W 80/327; H10W 90/794

(57) ABSTRACT

Electronic modules are described that include a plurality of electrically conductive protection layers to facilitate hybrid bonding and enable solder bumping to a module substrate. In an embodiment, a module substrate includes a planar bonding surface, where the planar bonding surface includes a first set of metal bond pads, a second set of metal bond pads and a dielectric layer. An IC die may be directly bonded (e.g., hybrid bonded) to the dielectric layer and the first set of metal bond pads. Further, an electronic component may be bonded (e.g., solder bumped) to a plurality of electrically conductive contact terminals formed over the plurality of electrically conductive protection layers.

### BACKGROUND

### Field

Embodiments described herein relate to semiconductor packaging, and more particularly to hybrid bonding technology.

### Background Information

The current market demand for artificial intelligence (AI) technologies has significantly increased the need for high-performance memory solutions, particularly in applications such as deep learning, real-time analytics and autonomous driving. High bandwidth memory (HBM) and graphics double data rate (GDDR) are critical in meeting these demands due to their ability to provide almost real-time access to data. As a result, various multiple-die packaging solutions (e.g., system in package (SiP), etc.) incorporate such high-performance memory solutions to meet the current market demand for AI, and at the same time strive to meet the demand for higher die/component density devices.

There are many different possibilities for arranging multiple components in an SiP. For example, vertical integration of die in SiP structures has evolved into 2.5D solutions and 3D solutions. In 2.5D solutions, the multiple dies may be flip chip bonded on an interposer that may include through vias as well as fan out wiring. In one 3D solution, multiple dies may be stacked on top of one another on an SiP substrate, and connected with off-chip wire bonds or solder bumps. In other traditional 3D solutions, hybrid bonding using wafer on wafer (WoW) or chip on wafer (CoW) techniques may be utilized. In a WoW solution, the top and bottom device area dimensions are exactly matched, and each layer is restricted to one technology node. In a CoW solution, multiple top wafers (chips) can be integrated onto the same bottom wafer with defined area and technology node.

### SUMMARY

In embodiments, an electronic module may include a planar bonding surface, where the planar bonding surface includes a dielectric layer, a first set of metal bond pads and a second set of metal bond pads. A plurality of electrically conductive protection layers may be formed over the second set of metal bond pads, and a plurality of electrically conductive contact terminals may be formed over the plurality of electrically conductive protection layers. Further, an IC die may be directly bonded (e.g., hybrid bonded) to the dielectric layer and the first set of metal bond pads, and an electronic component (e.g., memory package) may be bonded (e.g., solder bumped) to the plurality of electrically conductive contact terminals located over the second set of metal bond pads.

### BRIEF DESCRIPTION OF THE DRAWINGS

FIG. 1A is a cross-sectional side view illustration of an electronic module that includes an IC die hybrid bonded to a first set of metal bond pads, and a memory package solder bumped to a plurality of electrically conductive contact terminals located above a second set of metal bond pads in accordance with embodiments.

FIG. 1B is a close-up view of the electronic module illustrated in FIG. 1A.

FIG. 2 is a flow chart of a method for assembling an electronic module that includes an electrically conductive protection layer, and a plurality of electrically conductive contact terminals formed over the electrically conductive protection layer in accordance with embodiments.

FIGS. 3A-3C are schematic cross-sectional side view illustrations of a method for assembling an electronic module that includes an electrically conductive protection layer, and a plurality of electrically conductive contact terminals formed over the electrically conductive protection layer in accordance with embodiments.

FIG. 4 is a flow chart of a method for assembling an electronic module that includes an IC die hybrid bonded to a first set of metal bond pads, and a memory package solder bumped to a plurality of electrically conductive contact terminals formed over a second set of metal bond pads in accordance with embodiments.

FIGS. 5A-5D are schematic cross-sectional side view illustrations of a method for assembling an electronic module that includes an IC die hybrid bonded to a first set of metal bond pads, and a memory package solder bumped to a plurality of electrically conductive contact terminals located above a second set of metal bond pads in accordance with embodiments.

### DETAILED DESCRIPTION

Heterogeneous integration refers to the integration of different types of integrated circuit (IC) dies as well as other components, such as memory packages, into a single package. Further, IC dies and memory packages may utilize different bonding technologies. For example, IC dies may utilize hybrid bonding technology for the mass production of high-density input/output (I/O) chips with ultra-small pad pitches. A traditional hybrid bonding sequence includes planarizing surfaces to achieve strict flatness and cleanliness requirements, dielectric-to-dielectric initial bonding at room temperature, heating to close dishing gaps, and then further heating to compress metal-to-metal bonds. On the other hand, memory packages may utilize well-established solder bumping technology, which is cost-effective and has higher throughput as compared to hybrid bonding, making it suitable for mass production. However, it has been observed that integrating both hybrid bonding technology and solder bumping technology in the same package can be problematic. For example, the flatness and cleanliness requirements of hybrid bonding technology are not compatible with the requirements of traditional bumping technology, which include the deposition of seed layers, the application of photoresist, electrical plating and downstream cleaning processes. Current industry solutions utilize a type of two-tiered approach in which the IC dies may be hybrid bonded to an interposer (first tier) and prepackaged into a 2.5D package, where the 2.5D package may then be flip chip mounted onto a routing substrate/circuit board (second tier) along with a memory package. However, such processes can be complicated and inefficient.

In embodiments, an electronic module may include an electrically conductive protection layer over the planar bonding surface of a module substrate, where the planar bonding surface includes a dielectric layer and multiple sets of metal bond pads. In such instances, the protection layer can serve as a base layer upon which a plurality of electrically conductive contact terminals (e.g., stud bumps, etc.) may be formed over one set of metal contact pads, where third-party components (e.g., memory packages) may be ultimately solder bumped to the electrically conductive contact terminals. In addition, during formation of the electrically conductive contact terminals, the electrically conductive protection layer can also serve as a type of “hard mask” over another set of metal contact pads to preserve the planarity and cleanliness of the planar bonding surface for hybrid bonding to the module substrate. After formation of the electrically conductive contact terminals, the exposed portions of the electrically conductive protection layer may be removed to form a plurality of electrically conductive protection layers located directly under the plurality of electrically conductive contact terminals and directly above the module substrate. In such instances, IC dies may be hybrid bonded to one set of metal bond pads of the planar bonding surface previously covered/protected by the electrically conductive protection layer, and electronic components may be solder bumped to the plurality of electrically conductive contact terminals located over another set of metal bond pads of the planar bonding surface. In this way, the embodiments described allow hybrid bonded components and solder bumped components to coexist on the same wafer (or same tier).

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

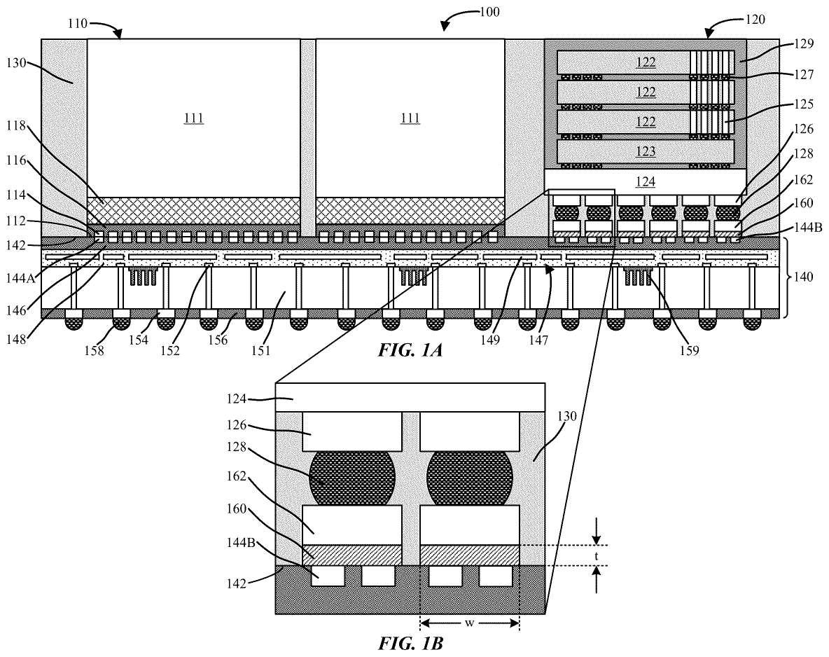

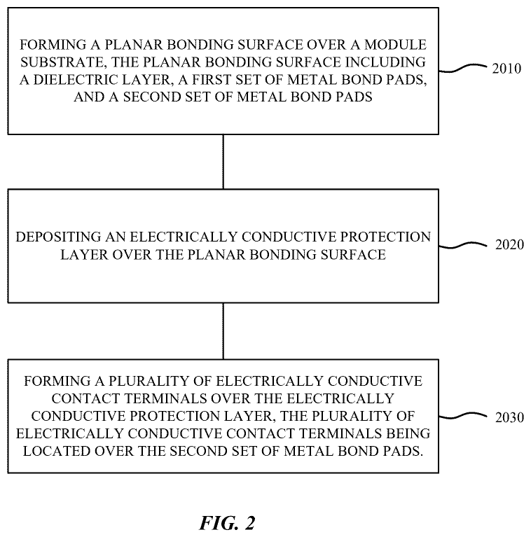

Referring now to FIGS. 1A-1B, FIG. 1A is a cross-sectional side view illustration of an electronic module that includes an IC die hybrid bonded to a first set of metal bond pads, and a memory package solder bumped to a plurality of electrically conductive contact terminals formed over a second set of metal bond pads in accordance with embodiments; FIG. 1B is a close-up view of the electronic module illustrated in FIG. 1A. As shown in FIGS. 1A-1B, electronic module 100 may include a plurality of IC dies 110 and electronic component 120. The plurality of IC dies 110 may be the same type of die or different types of dies. Various exemplary dies 110 may include system-on-chip (SOC), graphics processing unit (GPU), central processing unit (CPU), artificial intelligence (AI), machine learning logic, radio-frequency (RF) baseband processor, radio-frequency (RF) antenna, signal processors, power management integrated circuit (PMIC), logic, memory, photonics, biochips, low speed and/or high speed input/output (HSIO), cache, a silicon interconnect and any combinations thereof. In addition, the plurality of IC dies 110 may include a semiconductor layer 111 and a back-end-of-the-line (BEOL) build up structure 118. The semiconductor layer 111 may be a bulk silicon substrate, silicon-on-insulator substrate, etc. and may have an epitaxial device layer over the bulk silicon. It should be noted that silicon is exemplary and that other semiconductor substrate materials may be used. The BEOL build-up structure 118 may include electrical routing as is customary, as well as metal sealing structures (e.g., seal rings) to provide mechanical integrity and function as a physical barrier to moisture and impurity ingress. Further, electronic component 120 may be logic or memory, which can be single die or multi-die stacks. A variety of memory die stacks can be used such as dynamic random-access memory (DRAM), high bandwidth memory (HBM), double data rate (DDRx), low-power double data rate (LPDDRx), etc., where the embodiments are not limited to the exact memory stack-up illustrated in FIG. 1A. In the example of FIG. 1A, electronic component 120 may include stacked memory dies 122 connected to buffer die 123 and package substrate 124 by solder bumps 127 (e.g., microbumps) and through vias 125, where the stacked memory dies 122 and buffer die 123 may be encapsulated by molding compound 129. In addition, electronic component 120 may also include contact terminals 126 (e.g., under bump metallization, etc.) to facilitate the bonding of electronic component 120 to module substrate 140.

In further reference to FIGS. 1A-1B, IC die 110 and electronic component 120 may be bonded to module substrate 140. Module substrate 140 may include routing layer 147 and bulk layer 151. The routing layer 147 may include one or more dielectric layers 148 and one or more redistribution lines 149. The one or more dielectric layers 148 may be formed by standard deposition techniques (e.g., lamination, spin coating, spray coating, physical vapor deposition, chemical vapor deposition, etc.) and may include suitable materials to provide features such as isolating interconnect levels, stress buffering, etc. The one or more redistribution lines 149 may be embedded (e.g., embedded traces) in the dielectric layer(s) 148, and may include, but are not limited to, metallic materials such as copper, titanium, nickel, gold, and combinations or alloys thereof. Bulk layer 151 may be a bulk silicon substrate but may alternatively be substituted with another bulk material such as glass. Further, a plurality of through vias 152 (e.g., through silicon vias, etc.) may connect to routing layer 147 and extend through bulk layer 151 to backside dielectric layer 156 and connect with contact terminals 154 onto which solder bumps 158 (or solder tips) may be placed. In addition, module substrate 140 may include structures or devices to manage power fluctuations and improve signal quality, such as deep trench capacitors 159, etc. Further still, IC die 110 and electronic component 120 may be encapsulated by gap fill material 130. In some embodiments gap fill material 130 may include a molding compound (e.g., epoxy molding compound, etc.) to encapsulate the IC dies, whereas in other embodiments gap fill material 130 may include other suitable material that may be deposited rather than molded to encapsulate the IC dies (e.g., oxides, silicon, etc.).

Still referring to FIGS. 1A-1B, die 110 may be directly bonded to module substrate 140. Direct bonding may be accomplished using suitable techniques, such as fusion bonding (e.g., dielectric-dielectric bonds) or hybrid bonding (e.g., metal-metal bonds and dielectric-dielectric bonds), where the dielectric materials used by hybrid and/or fusion bonding can be inorganic-based or organic-based materials. In the example of FIG. 1A, die 110 may include planar bonding surface 112, a plurality of metal bond pads 114, and dielectric bonding layer 116 on BEOL build-up structure 118. Similarly, module substrate 140 may include planar bonding surface 142, a first set of metal bond pads 144A, a second set of metal bond pads 144B and dielectric bonding layer 146 on routing layer 147. In such instances, the first set of metal bond pads 144A and the second set of metal bond pads 144B may have the same (or substantially similar) pitch size so as to maintain the planarity of planar bonding surface 142. Dielectric bonding layers 116, 146 may be an insulating material, such as an oxide (e.g., silicon oxide, silicon nitride, silicon carbon nitride, etc.). Further, planar bonding surfaces 112, 142 may be planarized (e.g., chemical mechanical polishing (CMP)) to facilitate fusion or hybrid bonding, where such planarized bonding surfaces may be directly bonded to one another at (and diffused across) a bonding interface. In such instances, the maximum roughness average (Ra) of planar bonding surfaces 112, 142 may be 10 nm to prevent voids or other defects from forming at the bonding interface.

It has been observed that the requirements for hybrid bonding interfaces are not compatible with traditional bumping technology. For example, hybrid bonding requires extremely high quality bonding interfaces, including flat and clean dielectric surfaces to trigger dielectric-bond formation and specific copper topography control to promote inter-diffusion between the copper bond pads, whereas solder bumping requires depositing seed layers, applying photoresist, electrical plating and downstream cleaning processes. For products that need both heterogeneous chip integration through bumping and chiplet interconnection through hybrid bonding, conventional methods add another level of interposer for the bumping process. However, such conventional methods can be complicated and involve multiple layers of bumping, multiple layers of through vias, multiple carriers during processing, etc., which can be inefficient and costly. In the embodiments described, electronic module 100 may include an electrically conductive protection layer 160 to preserve the planarity (and cleanliness) of planar bonding surface 142 over the first set of metal bond pads 144A during the formation of a plurality of electrically conductive contact terminals 162 located above the second set of metal bond pads 144B. After removal of the exposed portions of the electrically conductive protection layer 160, IC dies 110 may be directly bonded (e.g., hybrid bonded) to the first set of metal bond pads 144A and electronic components 120 may be bonded (e.g. flip chip bonded) to the plurality of electrically conductive contact terminals 162 located above the second set of metal bond pads 144B. In this way, third party components that use solder bumping technology (e.g., high bandwidth memory, etc.) and components that use hybrid bonding technology can coexist on the same wafer in a simplified structure.

Referring back to FIGS. 1A-1B, electronic module 100 may include a plurality of electrically conductive protection layers 160. The plurality of electrically conductive protection layers 160 may be any suitable conductive material (e.g., titanium, titanium nitride, etc.) and may be deposited as single or multi-layers stacks over planar bonding surface 142 by any suitable method (e.g., sputtering, etc.). It should be noted that the plurality of electrically conductive protection layers 160 illustrated in FIGS. 1A-1B is first deposited as a single electrically conductive protection layer over planar bonding surface 142, where the single electrically conductive protection layer serves a dual purpose. First, the single electrically conductive protection layer can protect planar bonding surface 142 by maintaining the strict planarity and cleanliness requirements for hybrid bonding surfaces during subsequent downstream processing and fabrication. In this way, the single electrically conductive protection layer serves as a type of “hard mask” over the hybrid bonding surface, as opposed to more traditional protection layers formed of softer polymer-based materials. Second, the single electrically conductive protection layer can serve as a base layer upon which a plurality of electrically conductive contact terminals 162 may be formed. In such instances, the plurality of electrically conductive contact terminals 162 (e.g., stud bumps, etc.) may be formed by any suitable method (e.g., electroplating, etc.) and may include a bulk metal layer (e.g., copper) as well as a finishing layer over the bulk layer (e.g., electroless nickel electroless palladium immersion gold (ENEPIG) structure, etc.) to enable the bonding of components, such as electronic component 120, to module substrate 140 (e.g., flip chip bonding, etc.). In the example of FIGS. 1A-1B, the plurality of electrically conductive contact terminals 162 may be formed over the second set of metal bond pads 144B. After formation of the plurality of electrically conductive contact terminals 162, exposed portions of the single electrically conductive protection layer may then be removed (e.g., etched) using the plurality of electrically conductive contact terminals 162 as an etch mask to form the plurality of electrically conductive protection layers 160 illustrated in FIGS. 1A-1B. In some embodiments, solder bumps 128 may be placed on the electrically conductive contact terminals 162 to bond electronic component 120 to module substrate 140. In other embodiments, solder bumps 128 may be provided on component 120 for flip chip mounting to module substrate 140 through the plurality of electrically conductive contact terminals 162.

In further reference to FIGS. 1A-1B, as shown the plurality of electrically conductive protection layers 160 protrude from planar bonding surface 142. In some embodiments, the thickness, t, of the plurality of electrically conductive protection layers 160 that protrude from planar bonding surface 142 may be between 0.01-1 microns (e.g., submicron range). It should be noted that the thickness, t, of the plurality of electrically conductive protection layers 160 is less than the thickness of a typical seed layer used for conventional under bump metallization layers so that the exposed portions of the electrically conductive protection layer may be readily removed so that such removal does not itself adversely affect the planarity or cleanliness of planar bonding surface 142. In addition, the width, w, of each of the plurality of electrically conductive protection layers may span across multiple metal bond pads in the second set of metal bond pads 144B. For example, as shown in the close-up view of FIG. 1B, each of the plurality of electrically conductive protection layers 160 span across two metal bond pads in the second set of metal bond pads 144B, although it is contemplated that the plurality of electrically conductive protection layers may span over different amounts of metal bond pads depending on the size of the electrically conductive protection layers and/or the size of the metal bond pads.

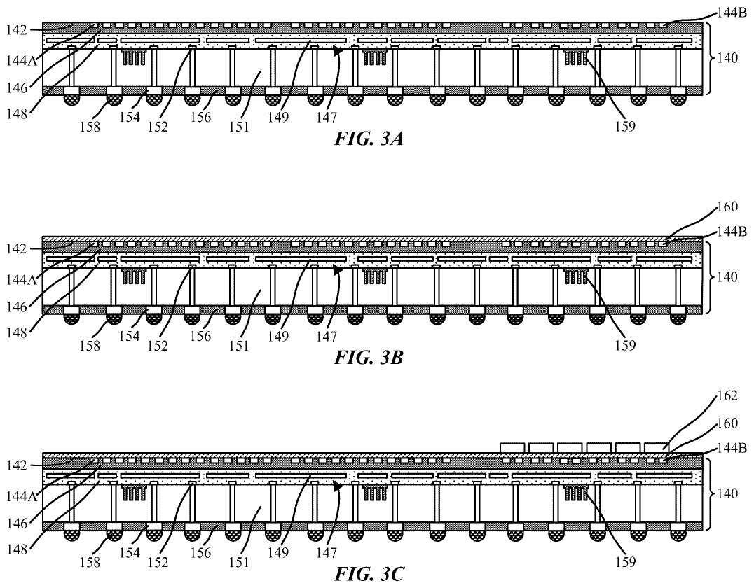

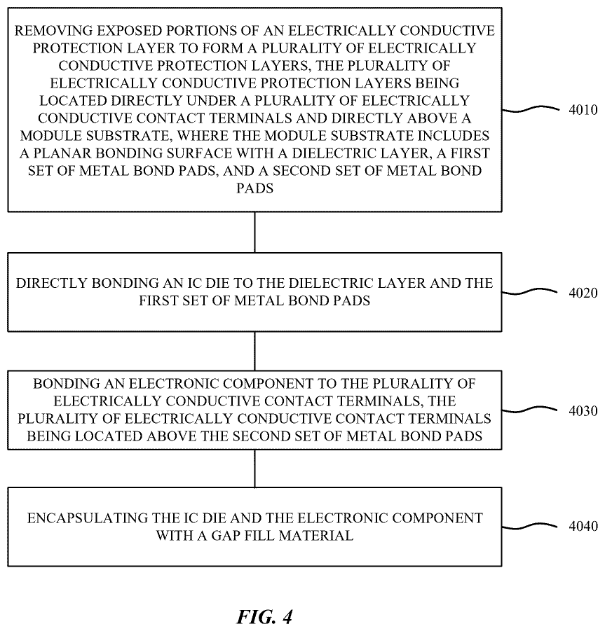

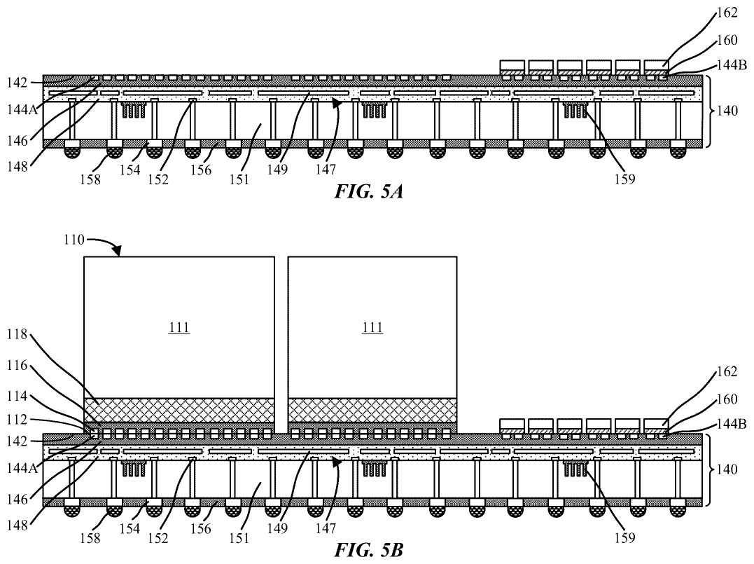

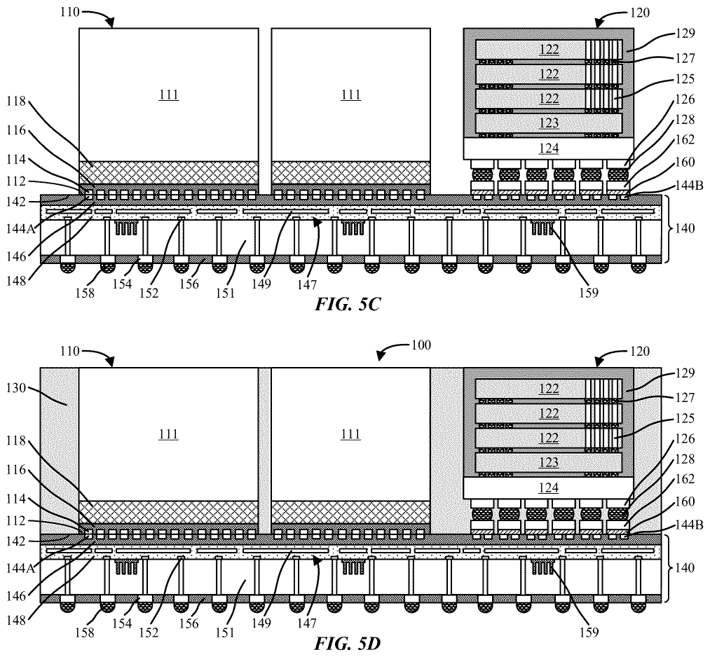

It should be noted that while the method for assembling electronic module 100 in accordance with embodiments may be performed by a single vendor, in practice the method for assembling electronic module 100 may be performed by multiple vendors. For example, a first vendor may perform a first method for depositing the electrically conductive protection layer over the planar bonding surface of the module substrate and then forming the plurality of electrically conductive contact terminals over the electrically conductive protection layer. Further, after the first method, the module substrate may be shipped to a second vendor (without degrading its hybrid bonding surface) where the second vendor may then perform a second method for removing the exposed portions of the electrically conductive protection layer, hybrid bonding an IC die to the module substrate, flip chip mounting a memory package to the module substrate, and then encapsulating the IC die and the electronic component with a gap fill material. As such, the method for assembling electronic module 100 has been broken up into two methods. More specifically, FIG. 2 and FIGS. 3A-3C describe a first method for depositing the electrically conductive protection layer 160 and forming electrically conductive contact terminals 162, whereas FIG. 4 and FIGS. 5A-5D describe a second method for removing exposed portions of the protection layer, hybrid bonding IC dies, flip chip mounting electronic components, and encapsulating the IC dies and electronic components. It should be understood that such methods are merely representative and that other variants (or other vendors) of the method(s) for assembling electronic module 100 in accordance with embodiments are also contemplated.

Referring now to FIG. 2 and FIGS. 3A-3C, FIG. 2 is a flow chart and FIGS. 3A-C are schematic cross-sectional side view illustrations of a method for assembling an electronic module that includes an electrically conductive protection layer, and a plurality of electrically conductive contact terminals formed over the electrically conductive protection layer in accordance with embodiments. In the interest of clarity and conciseness, the method of FIG. 2 is described concurrently with the illustrations of FIGS. 3A-3C. At operation 2010, planar bonding surface 142 may be formed over module substrate 140, as illustrated in FIG. 3A. Planar bonding surface 142 may include a first set of metal bond pads 144A, a second set of metal bond pads 144B and dielectric bonding layer 146 (e.g., silicon oxide, silicon nitride, silicon carbon nitride, etc.) over routing layer 147, where routing layer 147 may include one or more dielectric layers 148 and one or more redistribution lines 149 (e.g., embedded traces). In such instances, planar bonding surface 142 may be planarized (e.g., chemical mechanical polishing (CMP)) to achieve a roughness average (Ra) of the planar bonding surface no greater than 1 nm to facilitate hybrid bonding and to mitigate against defect formation at the hybrid bonding interface. Further, module substrate 140 may include a plurality of through vias 152 (e.g., through silicon vias, etc.) that connect to routing layer 147 and extend through bulk layer 151 to backside dielectric layer 156 and connect with contact terminals 154 onto which solder bumps 158 (or solder tips) may be placed. In some embodiments, module substrate 140 also includes one or more deep trench capacitors, such as deep trench capacitor 159.

Referring now to FIG. 3B, an electrically conductive protection layer 160 may be deposited over planar bonding surface 142 at operation 2020. The electrically conductive protection layer 160 may be any suitable conductive material (e.g., titanium, titanium nitride, etc.) and may be deposited over planar bonding surface 142 by any suitable method (e.g., sputtering, etc.). Further, the thickness of the electrically conductive protection layer 160 must be precisely controlled. For example, the electrically conductive protection layer 160 should be thick enough to preserve the planarity and cleanliness of planar bonding surface 142 during subsequent fabrication processes (e.g., depositing photoresist, patterning, electroplating, etc.), but also thin enough so that after completion of such fabrication processes the removal of the exposed portions of the electrically conductive protection layer 160 does not itself adversely affect the planarity or cleanliness of planar bonding surface 142. In some embodiments, the thickness of the electrically conductive protection layer 160 (and ultimately the plurality of electrically conductive protection layers 160) may be in the submicron range. At operation 2030, a plurality of electrically conductive contact terminals 162 (e.g., stud bumps, etc.) may be formed on the electrically conductive protection layer 160 above the second set of metal bond pads 144B, as illustrated in FIG. 3C. For example, a photoresist layer may be deposited and patterned to define the bumping region above the second set of metal bond pads 144B. Further, a bulk metal layer (e.g., copper) and a finishing layer over the bulk layer (e.g., electroless nickel electroless palladium immersion gold (ENEPIG) structure, etc.) may then be formed in the defined bumping regions located above the second set of metal bond pads 144B.

Referring now to FIG. 4 and FIGS. 5A-5D, FIG. 4 is a flow chart and FIGS. 5A-5D are schematic cross-sectional side view illustrations of a method for assembling an electronic module that includes an IC die hybrid bonded to a first set of metal bond pads, and a memory package solder bumped to a plurality of electrically conductive contact terminals located above a second set of metal bond pads in accordance with embodiments. In the interest of clarity and conciseness, the method of FIG. 4 is described concurrently with the illustrations of FIGS. 5A-5D. At operation 4010, the photoresist layer and the exposed portions of electrically conductive protection layer 160 not covered by the plurality of electrically conductive contact terminals 162 may then be removed (e.g., etched, etc.) to form the plurality of electrically conductive protection layers 160, as illustrated in FIG. 5A. In such instances, the plurality of electrically conductive protection layers 160 may be located directly under the plurality of electrically conductive contact terminals 162 and directly above module substrate 140. Further, the removal of the photoresist layer and the exposed portions of the electrically conductive protection layer 160 may be performed in such a manner so as to preserve the integrity of planar bonding surface 142 over the first set of metal bond pads 144A to facilitate hybrid bonding to the first set of metal bond pads 144A.

Referring now to FIG. 5B, IC die 110 may be directly bonded (e.g., hybrid bonded) to module substrate 140 at operation 4020. In such instances, IC die 110 may include a semiconductor layer 111 and BEOL build-up structure 118. During the hybrid bonding process, dielectric-dielectric bonds may be formed between dielectric bonding layer 146 of planar bonding surface 142 and dielectric bonding layer 116 of planar bonding surface 112. Further, after an annealing process, metal-metal bonds may be formed between the first set of metal bond pads 144A of planar bonding surface 142 and metal bond pads 114 of planar bonding surface 112 of IC die 110. At operation 4030, solder bumps 128 may be placed to bond electronic component 120 to module substrate 140, where the plurality of electrically conductive contact terminals 162 and the plurality of electrically conductive protection layers 160 establish the electrical connection between electronic component 120 and module substrate 140, as illustrated in FIG. 5C. In such instances, electronic component 120 (e.g., logic, memory, etc.) may include stacked memory dies 122 connected to buffer die 123 and package substrate 124 by solder bumps 127 (e.g., microbumps) and through vias 125, where the stacked memory dies 122 and buffer die 123 may be encapsulated by molding compound 129. An underfill material may then optionally be applied to the electronic component 120 to laterally surround the solder bumps 128, the plurality of electrically conductive contact terminals 162 and the plurality of electrically conductive protection layers 160, and fill the space underneath electronic component 120. At operation 4040, IC dies 110 and electronic component 120 may be encapsulated with gap fill material 130 (e.g., epoxy molding compound, oxide, silicon, etc.), as illustrated in FIG. 5D.

In utilizing the various aspects of the embodiments, it would become apparent to one skilled in the art that combinations or variations of the above embodiments are possible for forming an electronic module with a plurality of electrically conductive protection layers. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic module comprising:
a module substrate including a planar bonding surface, the planar bonding surface including a dielectric layer, a first set of metal bond pads, and a second set of metal bond pads;
an integrated circuit (IC) die directly bonded to the dielectric layer and the first set of metal bond pads;
a plurality of electrically conductive protection layers formed over the second set of metal bond pads;
a plurality of electrically conductive contact terminals formed over the plurality of electrically conductive protection layers;
an electronic component bonded to the plurality of electrically conductive contact terminals; and
a gap fill material that encapsulates the IC die and the electronic component.

2. The electronic module of claim 1, wherein each electrically conductive protection layer in the plurality of electrically conductive protection layers spans over multiple metal bond pads in the second set of metal bond pads.

3. The electronic module of claim 1, wherein the plurality of electrically conductive protection layers protrude from the planar bonding surface.

4. The electronic module of claim 1, wherein a thickness of the plurality of electrically conductive protection layers is between 0.01-1 microns.

5. The electronic module of claim 1, wherein a first pitch size of the first set of metal bond pads is the same as a second pitch size of the second set of metal bond pads.

6. The electronic module of claim 1, wherein the plurality of electrically conductive protection layers comprise titanium.

7. The electronic module of claim 1, wherein the plurality of electrically conductive protection layers comprise titanium nitride.

8. The electronic module of claim 1, wherein the plurality of electrically conductive contact terminals are stud bumps.

9. The electronic module of claim 1, wherein the electronic component is solder bumped to the plurality of electrically conductive contact terminals.

10. The electronic module of claim 1, wherein the electronic component is a high bandwidth memory.

11. The electronic module of claim 1, wherein the IC die is hybrid bonded to the module substrate.

12. The electronic module of claim 1, wherein the IC die is a system-on-chip.

13. The electronic module of claim 1, wherein a maximum roughness average (Ra) of the planar bonding surface is 10 nm.

14. A method comprising:
forming a planar bonding surface over a module substrate, the planar bonding surface including a dielectric layer, a first set of metal bond pads, and a second set of metal bond pads;
depositing an electrically conductive protection layer over the planar bonding surface; and
forming a plurality of electrically conductive contact terminals over the electrically conductive protection layer, the plurality of electrically conductive contact terminals being located above the second set of metal bond pads.

15. The method of claim 14, wherein forming the planar bonding surface includes performing chemical mechanical polishing of the module substrate to achieve a maximum roughness average (Ra) of 1 nm of the planar bonding surface.

16. The method of claim 14, wherein the electrically conductive protection layer comprises titanium, and a thickness of the electrically conductive protection layer is between 0.01-1 microns.

17. A method comprising:
removing exposed portions of an electrically conductive protection layer to form a plurality of electrically conductive protection layers, the plurality of electrically conductive protection layers being located directly under a plurality of electrically conductive contact terminals and directly above a module substrate, wherein the module substrate includes a planar bonding surface with a dielectric layer, a first set of metal bond pads, and a second set of metal bond pads;
directly bonding an IC die to the dielectric layer and the first set of metal bond pads;
bonding an electronic component to the plurality of electrically conductive contact terminals, the plurality of electrically conductive contact terminals being located over the second set of metal bond pads; and
encapsulating the IC die and the electronic component with a gap fill material.

18. The method of claim 17, wherein each electrically conductive protection layer in the plurality of electrically conductive protection layers spans over multiple metal bond pads in the second set of metal bond pads.

19. The method of claim 17, wherein the IC die is hybrid bonded to the module substrate.

20. The method of claim 17, wherein the electronic component is solder bumped to the plurality of electrically conductive contact terminals.
